(19) United States
(12) Patent Application Publication
(10) Pub. No.: US 2008/0224604 A1
(43) Pub. Date: Sep. 18, 2008

(54) DISPLAY

(76) Inventors: Tasuku Satou, Kanagawa (JP); Toshiro Takahashi, Kanagawa (JP)

Correspondence Address: BIRCH STEWART KOLASCH & BIRCH, PO BOX 747, FALLS CHURCH, VA, 22040-0747, US

(21) Appl. No.: 12/043,775

(22) Filed: Mar. 6, 2008

(30) Foreign Application Priority Data
Mar. 13, 2007 (JP) 2007-063944

(51) Int. Cl. H01J 1/54; H01L 51/50

(52) U.S. Cl. 313/504; 313/112

(57) ABSTRACT

A display by an active matrix drive in which a plurality of pixels are independently controlled, wherein each pixel includes at least two sub-pixels that emit light having the same color as each other by application of current to the sub-pixels, and at least one of the sub-pixels is provided with an optical filter at a light extraction side of the sub-pixel. A display which is capable of multi-gradation reproduction is provided.

### CROSS-REFERENCE TO RELATED APPLICATION

This application claims priority under 35 USC 119 from Japanese Patent Application No. 2007-063944, the disclosure of which is incorporated by reference herein.

### BACKGROUND OF THE INVENTION

1. Field of the Invention

The present invention relates to a display using a light-emitting element. In particular, the invention relates to a display that has improved gradation reproducibility and is capable of multi-gradation reproduction.

2. Description of the Related Art

Recently, flat panel displays with a thin shape and light weight have been used in wide fields in replace of Braun tubes (CRTs), and applications thereof have been extended. This has resulted from the accelerated spread of personal information terminals such as personal computers and cellular telephones compatible with network access, due to the development of information devices and infrastructure for service networks having the Internet as a core. In addition, the market for flat panel displays has expanded to home use television sets, which was conventionally the exclusive market of CRTs.

Liquid crystal displays (LCDs) already occupy a large market share due to such characteristics as a thin shape and light weight and low power consumption, but there are disadvantages to be improved with respect to some display characteristics, such as a viewing angle, contrast and response speed. Accordingly, the improvement of LCDs themselves has been advanced, and on the one hand, research and development with respect to displays based on completely different devices or principles have also been actively conducted.

Among these, as a device recently getting a lot of attention in particular, there is an organic eleoctroluminescence display (OELD). An OELD is a display that emits light corresponding to electric signals and is constituted using an organic compound as a light-emitting material. The OELD inherently has inherently excellent display characteristics such as a wide viewing angle, high contrast and high-speed response. Further, there is a possibility that it can realize displays of from a small size to a large size with a thin shape and light weight and high image quality. Therefore, it has attracted attention as a display capable of replacing CRTs and LCDs.

Concerning a driving technique of a matrix panel arranged with plural pixels, for OELDs as well, both duty driving (time-division driving) and static driving have been developed, similarly as in the case of displays such as LCDs.

The former has a simple panel structure resulting in a simple and low cost process. However, when the number of scanning lines increases, the emission period of respective lines relative to the period for scanning the whole screen decreases. As a result, for the purpose of obtaining required panel brightness, the peak brightness of pixels becomes high. When compared with driving conditions of full-time lighting, usually, this results in poor light-emission efficiency to require driving by high voltage or current.

Further, due to power loss in wiring portions, a larger a screen becomes, the more disadvantageous this is with respect to power consumption.

In contrast, since the latter is combined with nonlinear elements such as a thin film transistor (TFT), the process becomes complex. However, since such a constitution is possible in which an emission duration is maintained for the scanning period of one line, or longer, low power consumption and long operating life can be expected due to the decrease in the peak brightness of pixels and current.

As the TFT, a TFT of poly-silicon (p-Si) type such as continuous grain silicon (CGS) that has a high density patterning and high current driving performance is preferable. A high mobility and integration property, which are characteristics of the p-Si type TFT as an element, also make it possible to build such constituents as a driving IC (integrated circuit) and control circuit into a panel. For these reasons, technical development for active driving of an OELD is currently the main stream.

When performing active driving, the driving current necessary for obtaining a predetermined brightness per one pixel is several micro amperes at the maximum, and, in order to obtain a wide range of gradation reproduction, the minimum difference in current between respective gradations is a very minute value of several tens of nanoamperes. Control variation of a TFT manufactured in an ordinary manner occurs at a range of current value that exceeds this minute current value. Therefore, there occurs such gradation trouble as the reversion of brightness due to the variation. Accordingly, as a method for controlling such a very minute current with a TFT, for example, Japanese Application Laid-Open (JP-A) No. 2001-147659 discloses generating a driving current with an exterior driving circuit, performing writing to a writing capacitor in a pixel by a driving current generated through the improvement of a TFT circuit in a pixel to enable an organic EL element to be driven with the driving current, thereby compensating for the variation in characteristics of a TFT in the pixel circuit to reduce the brightness variation. However, there are such problems to be solved in that one more TFT is required for controlling the TFT and heavy equipment is required for lowering the current and voltage of a TFT driving device.

Along with even more fine reproduction of a display, and further improvement of light-emission efficiency of a light-emitting element, the minimum current value to be controlled tends to be reduced more and more. Thus, a controlling method that has higher reliability and is convenient and compact is required.

JP-A No. 2003-280593, for example, discloses a display provided with a first sub-pixel for displaying multi-gradation including a halftone and a second sub-pixel having a smaller number of gradations. The first sub-pixel is controlled by an offset voltage switching means that switches offset voltage on the basis of the comparison between an analog signal and a reference signal, and the second sub-pixel is controlled by binary values of lightness and darkness. However, organic electroluminescence elements by voltage control have such a problem in that the brightness varies largely according to temperature variation and are not practical. On the other hand, JP-A No. 5-34702 discloses a liquid crystal display provided with sub-pixels having different areas from each other. The gradation of the liquid crystal display is also controlled by voltage, but, for a display in which gradation is controlled by current, it is impossible to perform gradation reproduction with high reliability only by providing sub-pixels having different areas from each other.

Regarding the current control and voltage control in an organic EL element, there is detailed description in “Organic EL Materials and Displays (Yuuki EL Zairyou to Disupurei)” edited by Junji Kido, pages 283-284, CMC (2001). Driving of an organic EL element is based on direct current driving in which a hole and an electron are injected into a light-emitting layer by applying a direct current electric field between an anode and a cathode, and the driving results from the fact that the emission brightness in the organic EL element is proportional to a value of the driving current. As shown on page 284, FIG. 3 of the above reference, current and brightness show very good linear relationship, and therefore, it is understood that the brightness can be stably controlled by current values. However, as shown in FIG. 4 on the same page of the reference, voltage and brightness are in a relationship similar to ON/OFF characteristics, which is suitable for pulse modulation control, but, in a case where it is used for the brightness control of an organic EL element, the brightness varies significantly according to a slight variation in voltage, which is not preferable. In particular, it is extremely difficult to display an image having multi-gradation with good reproducibility by a voltage control system.

Even in the case of a current control system, multi-gradation reproduction of images is not yet sufficient, and means for image reproduction having multi-gradation by a current control system is desired even further.

### SUMMARY OF THE INVENTION

The present invention has been made in view of the above circumstances and provides an organic electroluminescence element with the following aspect.

An aspect of the present invention is to provide a display by an active matrix drive in which a plurality of pixels are independently controlled, wherein each pixel comprises at least two sub-pixels that emit light having the same color as each other by application of current to the sub-pixels, and at least one of the sub-pixels is provided with an optical filter at a light extraction side of the sub-pixel.

### BRIEF DESCRIPTION OF THE DRAWINGS

FIG. 1 is a circuit diagram showing a display by a conventional active matrix drive.

FIG. 2 is a circuit diagram showing one embodiment of a display by an active matrix drive according to the present invention.

FIG. 3 is a conceptual diagram of a conventional array of pixels.

FIG. 4 is a conceptual diagram of an array of pixels including sub-pixels according to the invention.

FIG. 5 is a conceptual diagram showing the relationship between a current value and emission brightness. The horizontal axis shows a driving current value for an element, and the vertical axis shows emission brightness corresponding to respective current values, relatively in arbitrary units. The mark (A) represents brightness in a conventional array of pixels without a difference in emission brightness. The mark (□) represents the brightness of a sub-pixel having a higher light quantity in an array of pixels according to the invention. The mark (∘) represents the brightness of a sub-pixel which is provided with an optical filter and has a lower light quantity.

FIG. 6 is a cross-sectional view showing a configuration of an organic EL element according to the invention.

### DETAILED DESCRIPTION OF THE INVENTION

An object of the present invention is to provide a display using light-emitting elements, and more specifically to provide a display that is improved with respect to gradation control, and thereby to provide a display exhibiting stable multi-gradation reproduction.

The above object of the invention has been achieved by a display by an active matrix drive in which a plurality of pixels are independently controlled, wherein each pixel has at least two sub-pixels that emit light having the same color as each other by application of current to the sub-pixels, and at least one of the sub-pixels is provided with an optical filter at a light extraction side of the sub-pixel.

Preferably, the optical filter has a transmission optical density for reducing a light quantity to a range of from 5% to 60%.

The light emission area of the sub-pixel having the optical filter is preferably smaller than the light emission area of the sub-pixel that does not have the optical filter.

The number of gradations of the sub-pixel having the optical filter is preferably smaller than the number of gradations of the sub-pixel that does not have the optical filter.

The light-emitting element used in the sub-pixel having the optical filter and the light-emitting element used in the sub-pixel that does not have the optical filter emit light having the same color, and both of the light-emitting elements are the same as each other, except for the presence or absence of the optical filter on a light extraction surface, and a difference in the light emission areas of the light-emitting elements. Namely, the light-emitting element of the sub-pixel having the optical filter is constituted by the same material as that of the sub-pixel that does not have the optical filter.

Preferably, the pixels comprise charge injection light-emitting elements, and the gradation reproduction by the pixels is controlled by means of current values to be applied.

The light-emitting element is preferably an organic electroluminescence element. A light emitting material of the organic electroluminescence element is preferably a phosphorescent material.

The organic electroluminescence element is preferably a top-emission organic electroluminescence element.

The display is preferably a full color display.

The present invention provides a display that has improved gradation reproducibility and that is capable of multi-gradation reproduction.

According to the invention, the display can represent multi-gradation in a range of stably controllable currents by providing a sub-pixel having low emission brightness for each pixel. Accordingly, reliability in gradation control can be improved so that high image quality even in a large sized display can be realized.

Hereinafter, the invention will be described in detail.

### 1. Display

The display of the present invention comprises a plurality of pixel portions including pixels having spontaneous light-emitting elements and an active element for controlling the pixels independently, wherein the pixel has at least two sub-pixels, and an optical filter is disposed on a light extraction surface of at least one sub-pixel to reduce the brightness to be extracted to the outside. The sub-pixels emit light having the same color as each other by application of current to the sub-pixels, and the brightness to be extracted to the outside is preferably reduced by the optical filter to a range of from 5% to 60%, more preferably from 10% to 50%, and even more preferably from 20% to 40% per unit of current. In the case where the reduction in the brightness exceeds 60%, the latitude in controlled current value becomes narrower, which is not preferred. In the case where the reduction in the brightness is less than 5%, the power consumption of a display panel increases, which is not preferred.

The light emission area of the sub-pixel on which the optical filter is disposed is smaller than the light emission area of the sub-pixel on which the optical filter is not disposed.

The ratio of the light emission area of the sub-pixel having the optical filter to the light emission area of the sub-pixel that does not have the optical filter is preferably from 0.01% to 100%, more preferably from 1% to about 50%, and even more preferably from 3% to 30%. In the case where the ratio exceeds 100%, the power consumption of a display panel increases, which is not preferred. In the case where the ratio is less than 0.01%, the manufacturing process of the sub-pixel having the optical filter becomes difficult, which is not preferred.

In the present invention, the brightness as extracted from the at least two sub-pixels to the outside are different from each other, and the brightness of at least one of the sub-pixels is reduced with the optical filter. The other sub-pixel is not substantially provided with an optical filter, but may be provided with an optical filter having a relatively low transmission density to an extent that the brightness thereof is different from the brightness of the sub-pixel having the optical filter described above. Alternately, the sub-pixels (overall sub-pixels or limited sub-pixels) may be provided with a color filter to adjust color tone of light.

As a method for obtaining the ratio of light quantities between the sub-pixels having different areas, the brightness of the display is measured while only the sub-pixel having the optical filter is lighted at a certain current density. Further, the brightness of the display is measured while only the sub-pixel that does not have the optical filter is driven at the same current density value as the above current density value. The brightness is measured by means of a spectral radiance meter or the like, and the display is disposed so that a great number of the sub-pixels to be measured are included within a measurement area. The ratio of light quantities is a ratio obtained by dividing the measured values by the aperture ratios (light emission area of sub-pixel/pixel area) of respective sub-pixels. Since the brightness of the sub-pixel having the optical filter is lower than that of the sub-pixel that does not have the optical filter in the invention, the value of “efficiency of sub-pixel having optical filter/efficiency of sub-pixel that does not have optical filter” becomes 1 or less. This value is preferably 0.5 or less, and more preferably 0.33 or less.

The optical filter may be disposed at any position as long as the filter is placed between the light-emitting element and an observer. The optical filter may have any structure as long as the filter absorbs light emitted from the element, and membranes of an organic material, metal foils or the like are preferably used. The optical filter preferably has a structure that absorbs light emitted from the element, but does not emit light itself.

The display of the invention is not specifically limited, but can be used for various known displays that require multi-gradation.

A number of colors corresponding to a number obtained by multiplying respective numbers of gradation capable of being reproduced for each emission color (for example, R, G and B) by each other can be reproduced. For example, a display can reproduce eight colors, in a case where each of the three colors has two reproduction values. With an increase in the number of reproducible colors, an image which is clearer and has higher contrast can be displayed, so that it is preferable to increase the number of gradations for each color as much as possible. However, as described above, in the conventional light-emitting element controlled by current value, the current value to be controlled is extremely small, so that there are problems in that it is difficult to control the multi-gradation with high reliability (depending on the performance of current control mechanisms of such as a TFT). According to the invention, multi-gradation can be achieved in the current value region in which the performance of the TFT can be controlled with high reliability.

The displays using the structure of the invention can be suitably used for monocolor or full color displays. Examples of the monocolor displays include a multi-gradation display for displaying X-ray photographs and the like, and examples of the full color displays include a home-use TV display and the like.

The pixel is preferably a current excitation type light-emitting element, more preferably an organic electroluminescence element (hereinafter, sometimes referred to as an “organic EL element” in the invention), and particularly preferably a top-emission type organic electroluminescence element. The display is preferably a full color display.

Next, the display of the invention will be described in detail with reference to the drawings.

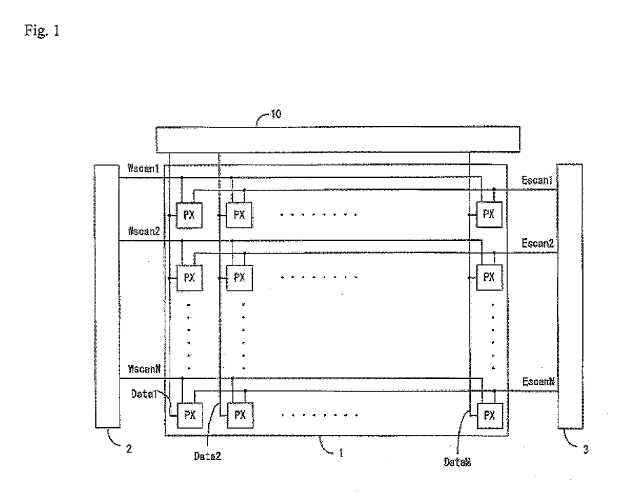

FIG. 1 is a configurational drawing of a display. For example, the display is an organic EL display utilizing an organic electroluminescence element. The display panel 1 includes a plurality of first scanning lines Wscan 1 to N and a plurality of second scanning lines Escan 1 to N provided in the horizontal direction, a plurality of data lines Data 1 to M provided in the vertical direction, and sub-pixels PX provided at the intersections thereof. Within one frame period, a first scanning line driving circuit 2 scans the first scanning lines Wscan 1 to N sequentially, and the second scanning line driving circuit 3 scans the second scanning lines Escan 1 to N sequentially, and in each scanning period, a data line driving circuit 10 supplies writing current Iw corresponding to brightness information to data lines Data 1 to M. In the display of the invention, the PX is constituted, for example, by repeating LR (sub-pixel that does not have optical filter), sR (sub-pixel having optical filter) such as LR, sR, LR and so on in the vertical direction, and by repeating, for example, LR, LG, LB, LR, LG, LB and so on in the horizontal direction.

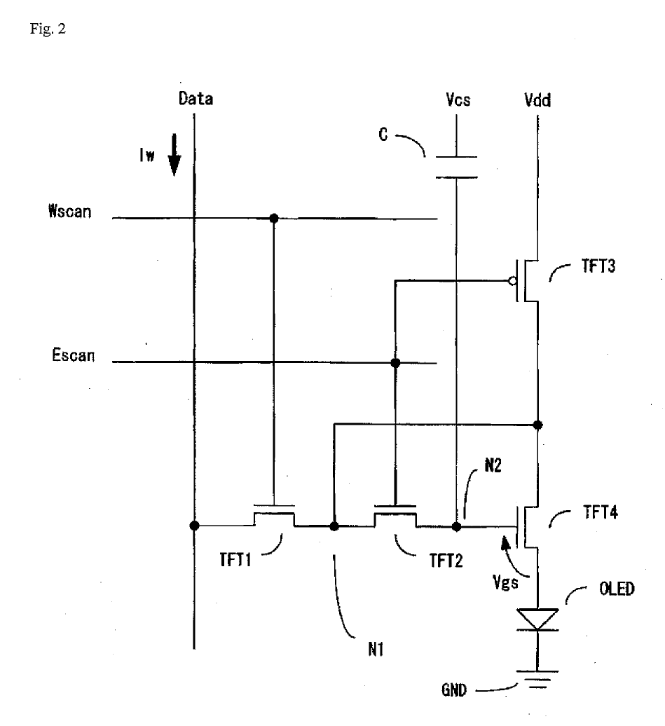

FIG. 2 is a drawing showing a pixel circuit of a display according to the present embodiment. The sub-pixel PX includes a light-emitting element OLED such as an organic EL element that emits light with brightness in accordance with a drive current, a drive transistor TFT4 that supplies a drive current to the light-emitting element OLED, a third transistor TFT3 that connects the drain of the drive transistor TFT4 to a power source Vdd, a first transistor TFT1 whose gate is connected to the first scanning line Wscan, a second transistor TFT2 whose gate is connected to the second scanning line Escan, and a condenser C disposed between the gate of the drive transistor TFT4 and a predetermined constant power voltage source Vcs. Only the third transistor TFT3 is a P-type transistor, and the other transistors are N-type transistors.

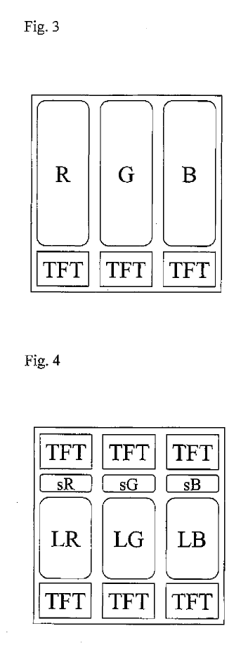

FIG. 3 schematically shows a conventional pixel array. In the array, sub-pixels of red, green and blue necessary for displaying an image in full color are arrayed, and each of the sub-pixels emits light with a desired brightness to represent a desired color. The number of reproducible colors is determined according to the number of gradations of each sub-pixel in each color. For example, in a case where each color can reproduce 256 gradations, approximately 16,770,000 colors can be represented. In the case where the current value per one sub-pixel for reproducing the maximum gradation (maximum current value) is, for example, 4 μA, the difference in current values between the gradations is 15.6 nA based on a simple calculation. It is extremely difficult to control such a minute current in common TFTs with high reproducibility due to the influence of wiring capacity or the like.

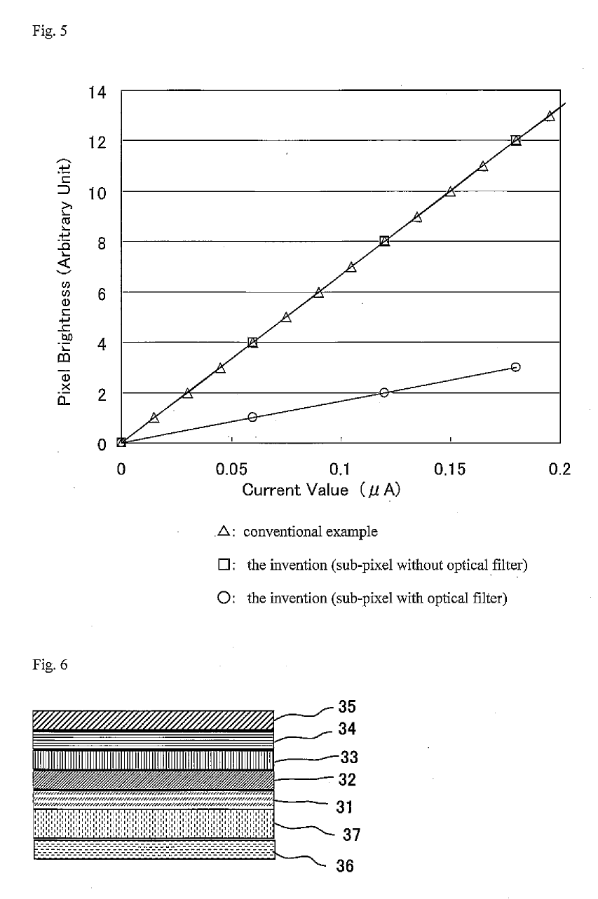

FIG. 4 shows a pixel array according to the invention. In the invention, sub-pixels with lower brightness are arrayed. As shown in FIG. 4, the sub-pixels sR, sG and sB, each having reduced brightness, are added to the sub-pixels LR, LG and LB, respectively. The sub-pixels LR, LG and LB are set to have a higher light quantity and a larger area. 64 gradations are reproduced with sub-pixels LR, LG and LB, and 4 gradations are reproduced with sub-pixels sR, sG and sB, respectively. Thus, 256 gradations for each color can be reproduced. The brightness of sR, sG and sB are, for example, approximately ¼ of that of LR, LG and LB, and therefore, the difference in current values between the gradations is approximately 4 times that in the conventional configuration, which is around 62 nA as shown in FIG. 5.

As is clear from the current values, the tolerance of fluctuation in the current values in the configuration of the invention is about 4 times larger than that of the conventional configuration. The sub-pixels sR, sG and sB are responsible for the reproduction of minute gradations, whereby displays capable of reproducing approximately 16,770,000 colors with the 256 gradations for each color can be realized. In short, it is sufficient that the number of gradations and light quantity of the sub-pixels sR, sG and sB are reduced such that the minimum control current values between gradations become current values which are controllable with high reliability. However, in the case where only the areas of the sub-pixels are changed without changing the light quantity thereof, the controlled current values do not change, and thus, no gains can be obtained in the case of current control.

Accordingly, according to the invention, it is possible that multi-gradation can be reproduced in a stably controllable current range by providing a sub-pixel with lower brightness for each pixel. According to the invention, the reliability of the gradation control can be improved, and high image quality can be realized even in a large screen display.

FIG. 6 is a cross-sectional view of a configuration of an organic electroluminescence element used in the invention. The organic electroluminescence element comprises, on a transparent substrate 37, an anode 31, a hole transport layer 32, a light-emitting layer 33, an electron transport layer 34 and a cathode 35. An optical filter is disposed on the opposite side of the transparent substrate from these layers.

The light emitted from the element by applying current thereto passes through the transparent substrate, and is extracted to the outside with brightness reduced by the optical filter.

### 2. Organic EL Element

The organic electroluminescence element according to the present invention may include a known organic compound layer including a hole transport layer, an electron-transport layer, a blocking layer, an electron injection layer, a hole injection layer and the like, as well as a light-emitting layer.

In the following, the explanation will be presented in more detail.

1) Layer Configuration

<Electrode>

At least one of a pair of electrodes of the organic electroluminescence element according to the present invention is a transparent electrode, and the other one is a rear surface electrode. The rear surface electrode may be transparent or non-transparent.

<Configuration of Organic Compound Layer>

A layer configuration of the above described organic compound layer can be appropriately selected, without particular restriction, depending on an application of the organic electroluminescence element and an object thereof. However, the organic compound layers is preferably formed on the transparent electrode or on the rear surface electrode. In these cases, the organic compound layer is formed on front surfaces or one surface on the transparent electrode or the rear surface electrode.

A shape, size, thickness and the like of the organic compound layer can be appropriately selected, without particular restriction, depending on applications thereof.

Specific examples of layer configuration include those cited below, but the present invention is not restricted to those examples.

Anode/hole-transport layer/light-emitting layer/electron-transport layer/cathode,

Anode/hole-transport layer/light-emitting layer/blocking layer/electron-transport layer/cathode,

Anode/hole-transport layer/light-emitting layer/blocking layer/electron-transport layer/electron-injection layer/cathode,

Anode/hole-injection layer/bole-transport layer/light-emitting layer/blocking layers electron-transport layer/cathode, and

Anode/hole-injection layer/hole-transport layer/light-emitting layer/blocking layer/electron-transport layer/electron-injection layer/cathode.

Each layer will be described in detail below.

2) Hole-Transport Layer

The hole-transport layer that is used in the present invention includes a hole transporting material. For the hole transporting material, any material can be used without particular restriction as far as it has either one of a function of transporting holes or a function of blocking electrons injected from the cathode. As the hole transporting material that can be used in the present invention, either one of a low-molecular hole transporting material and a polymer hole transporting material can be used.

Specific examples of the hole transporting material that can be used in the present invention include a carbazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, a polysilane-based compound, a poly(N-vinylcarbazole) derivative, an aniline-based copolymer, electric conductive polymers or oligomers such as a thiophene oligomer and polythiophene, and polymer compounds such as a polythiophene derivative, a polyphenylene derivative, a polyphenylenevinylene derivative and a polyfluorene derivative.

These compounds may be used alone or in a combination of two or more of them.

A thickness of the hole-transport layer is preferably from 10 nm to 400 nm and more preferably from 50 nm to 200 nm.

3) Hole-Injection Layer

In the present invention, a hole-injection layer may be disposed between the hole-transport layer and the anode.

The hole-injection layer is a layer that makes it easy for holes to be injected from the anode to the hole-transport layer, and specifically, a material having a small ionization potential among the hole transporting materials cited above is preferably used. For instance, a phthalocyanine compound, a porphyrin compound and a star-burst type triarylamine compound can be preferably used.

A film thickness of the hole-injection layer is preferably from 1 nm to 300 nm.

4) Light-Emitting Layer

The light-emitting layer which is used in the present invention comprises at least one light emitting material, and may comprise as necessary other materials such as a hole transporting material, an electron transporting material, and a host material.

Any of light emitting materials can be used without particular restriction. Either of fluorescent materials or phosphorescent materials can be used, but the phosphorescent materials are preferred in view of the light-emission efficiency.

Examples of the above-described fluorescent materials include, for example, a benzoxazole derivative, a benzimidazole derivative, a benzothiazole derivative, a styrylbenzene derivative, a polyphenyl derivative, a diphenylbutadiene derivative, a tetraphenylbutadiene derivative, a naphthalimide derivative, a coumalin derivative, a perylene derivative, a perinone derivative, an oxadiazole derivative, an aldazine derivative, a pyralidine derivative, a cyclopentadiene derivative, a bis-styrylanthracene derivative, a quinacridone derivative, a pyrrolopyridine derivative, a thiadiazolopyridine derivative, a styrylamine derivative, aromatic dimethylidene compounds, a variety of metal complexes represented by metal complexes or rare-earth complexes of a 8-quinolynol derivative, polymer compounds such as a polythiophene derivative, a polyphenylene derivative, a polyphenylenevinylene derivative, and a polyfluorenone derivative, and the like. These compounds may be used alone or in a combination of two or more of them.

The phosphorescent material is not particularly limited, but an ortho-metal complex or a porphyrin metal complex is preferred.

The ortho-metal complex referred to herein is a generic designation of a group of compounds described in, for instance, Akio Yamamoto, Yuki Kinzoku Kagaku, Kiso to Oyo (“Organic Metal Chemistry, Fundamentals and Applications”) (Shokabo, 1982), pages 150 to 232, and H. Yersin, Photochemistry and Photophysics of Coordination Compounds (New York: Springer-Verlag, 1987), pages 71 to 77 and pages 135 to 146. The ortho-metal complex can be advantageously used as a light emitting material in the light-emitting layer because high brightness and excellent light-emission efficiency can be obtained.

As a ligand that forms the ortho-metal complex, various ligands can be cited and are described in the above-mentioned literature as well. Examples of preferable ligands include a 2-phenylpyridine derivative, a 7,8-benzoquinoline derivative, a 2-(2-thienyl)pyridine derivative, a 2-(1-naphtyl)pyridine derivative and a 2-phenylquinoline derivative. The derivatives may be substituted by a substituent as needs arise. Furthermore, the ortho-metal complex may have other ligands than the ligands mentioned above.

An ortho-metal complex used in the present invention can be synthesized according to various known processes such as those described in Inorg. Chem., 1991, vol. 30, page 1685; Inorg. Chem., 1988, vol. 27, page 3464; Inorg. Chem., 1994, vol. 33, page 545; Inorg. Chim. Acta, 1991, vol. 181, page 245; J. Organomet. Chem., 1987, vol. 335, page 293 and J. Am. Chem. Soc., 1985, vol. 107, page 1431.

Among the ortho-metal complexes, compounds emitting light from a triplet exciton can be preferably employed in the present invention from the viewpoint of improving light-emission efficiency.

Furthermore, among the porphyrin metal complexes, a porphyrin platinum complex is preferable.

The phosphorescent materials may be used alone or in a combination of two or more of them. Furthermore, a fluorescent material and a phosphorescent material may be simultaneously used.

A host material is a material that has a function of causing an energy transfer from an excited state thereof to the fluorescent material or the phosphorescent material to cause light emission from the fluorescent material or the phosphorescent material.

As the host material, as long as a compound can transfer exciton energy to a light emitting material, any compound can be appropriately selected and used depending on an application without particular restriction. Specific examples thereof include: a carbazole derivative; a triazole derivative; an oxazole derivative; an oxadiazole derivative; an imidazole derivative; a polyarylalkane derivative; a pyrazoline derivative; a pyrazolone derivative; a phenylenediamine derivative; an arylamine derivative; an amino-substituted chalcone derivative; a styrylanthracene derivative; a fluorenone derivative; a hydrazone derivative; a stilbene derivative; a silazane derivative; an aromatic tertiary amine compound; a styrylamine compound; an aromatic dimethylidene-based compound; a porphyrin-based compound; an anthraquinonedimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; a variety of metal complexes represented by metal complexes of a 8-quinolinol derivative, metal phthalocyanine, and metal complexes with benzoxazole or benzothiazole as a ligand; polysilane compounds; a poly(N-vinylcarbazole) derivative; an aniline-based copolymer; electric conductive polymers or oligomers such as a thiophene oligomer and polythiophene; polymer compounds such as a polythiophene derivative, a polyphenylene derivative, a polyphenylenevinylene derivative and a polyfluorene derivative; and like.

These compounds can be used alone or in a combination of two or more of them.

A content of the host material in the light-emitting layer is preferably in a range of from 0% to 99.9% by weight and more preferably in a range of from 0% to 99.0% by weight.

5) Blocking Layer

In the present invention, a blocking layer may be disposed between the light-emitting layer and the electron-transport layer. The blocking layer is a layer that inhibits excitons generated in the light-emitting layer from diffusing and holes from penetrating to a cathode side.

A material that is used in the blocking layer may be a general electron transporting material, as long as it can receive electrons from the electron-transport layer and deliver them to the light-emitting layer, without being particularly restricted. Examples thereof include a triazole derivative, an oxazole derivative; an oxadiazole derivative; a fluorenone derivative; an anthraquinodimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; a variety of metal complexes represented by metal complexes of a 8-quinolinol derivative, metal phthalocyanine, and metal complexes with benzoxazole or benzothiazole as a ligand; electric conductive polymers oligomers such as an aniline-based copolymer, a thiophene oligomer and polythiophene; and polymer compounds such as a polythiophene derivative, a polyphenylene derivative, a polyphenylenevinylene derivative and a polyfluorene derivative. These compounds can be used alone or in a combination of two or more of them.

6) Electron-Transport Layer

In the present invention, an electron-transport layer including an electron transporting material can be disposed.

The electron transporting material can be used without particular restriction, as long as it has either one of a function of transporting electrons or a function of blocking holes injected from the anode. The electron transporting materials that are cited above in the explanation of the blocking layer can be preferably used.

A thickness of the electron-transport layer is preferably from 10 nm to 200 nm and more preferably from 20 nm to 80 nm.

When the thickness exceeds 1000 nm, the driving voltage increases in some cases. When it is less than 10 nm, the light-emission efficiency of the light-emitting element may be greatly deteriorated, which is not preferable.

7) Electron-Injection Layer

In the present invention, an electron-injection layer can be disposed between the electron-transport layer and the cathode.

The electron-injection layer is a layer by which electrons can be readily injected from the cathode to the electron-transport layer. Specifically, lithium salts such as lithium fluoride, lithium chloride and lithium bromide; alkali metal salts such as sodium fluoride, sodium chloride and cesium fluoride; and electric insulating metal oxides such as lithium oxide, aluminum oxide, indium oxide and magnesium oxide can be preferably used.

A film thickness of the electron-injection layer is preferably from 0.1 nm to 5 nm.

8) Substrate

The substrate to be applied in the present invention is preferably impermeable to moisture or very slightly permeable to moisture. Furthermore, the substrate preferably does not scatter or attenuate light emitted from the organic compound layer. Specific examples of materials for the substrate include YSZ (zirconia-stabilized yttrium); inorganic materials such as glass; polyesters such as polyethylene terephthalate, polybutylene phthalate and polyethylene naphthalate; and organic materials such as polystyrene, polycarbonate, polyethersulfone, polyarylate, aryldiglycolcarbonate, polyimide, polycycloolefin, norbornene resin, polychlorotrifluoroethylene, and the like.

In the case of employing an organic material, it is preferred to use a material excellent in heat resistance, dimensional stability, solvent-resistance, electrical insulation, workability, low gas permeability, and low moisture-absorption. These can be used alone or in a combination of two or more of them.

There is no particular limitation as to the shape, the structure, the size and the like of the substrate, but it may be suitably selected according to the application, the purposes and the like of the light-emitting element. In general, a plate-like substrate is preferred as the shape of the substrate. The structure of the substrate may be a monolayer structure or a laminated structure. Furthermore, the substrate may be formed from a single member or from two or more members.

Although the substrate may be in a transparent and colorless, or a transparent and colored, it is preferred that the substrate is transparent and colorless from the viewpoint that the substrate does not scatter or attenuate light emitted from the light-emitting layer described above.

A moisture permeation preventive layer (gas barrier layer) may be provided on the front surface or the back surface on the transparent electrode side of the substrate. For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

A hard-coat layer or an under-coat layer may be further provided as necessary on the substrate.

9) Electrodes

Either one of the first electrode and the second electrode in the present invention can be an anode or a cathode. It is preferable that the first electrode is the anode and the second electrode is the cathode.

<Anode>

The anode in the present invention generally has a function as an anode for supplying holes to the organic compound layer, and while there is no particular limitation as to the shape, the structure, the size and the like of the anode, it may be suitably selected from among well-known electrodes according to the application and the purpose of the light-emitting element.

As materials for the anode, for example, metals, alloys, metal oxides, electric conductive compounds, and mixtures thereof are preferably used, wherein those having a work function of 4.0 eV or more are preferred. Specific examples of the anode materials include semiconducting metal oxides such as tin oxides doped with antimony, fluorine or the like (ATO, and FTO), tin oxide, zinc oxide, indium oxide, indium tin oxide (ITO), and indium zinc oxide (IZO); metals such as gold, silver, chromium, and nickel; mixtures or laminates of these metals and the electric conductive metal oxides; inorganic electric conductive materials such as copper iodide, and copper sulfide; organic electric conductive materials such as polyaniline, polythiophene, and polypyrrole; and laminates of these inorganic or organic electron-conductive materials with ITO.

The anode may be formed on the substrate, for example, in accordance with a method which is appropriately selected from among wet methods such as a printing method, and a coating method and the like; physical methods such as a vacuum deposition method, a sputtering method, and an ion plating method and the like; and chemical methods such as CVD and plasma CVD methods and the like with consideration of the suitability with a material constituting the anode. For instance, when ITO is selected as a material for the anode, the anode may be formed in accordance with a DC or high-frequency sputtering method, a vacuum deposition method, an ion plating method or the like. Further, when an organic electric conductive compound is selected as a material for the anode, the anode may be formed in accordance with a wet film forming method.

In the light-emitting element described above, a position at which the anode is to be formed is not particularly restricted, but it may be suitably selected according to the application and the purpose of the light-emitting element. The anode is preferably formed on the substrate. In this case, the anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, and a lift-off method or a printing method may be applied.

A thickness of the anode may be suitably selected dependent on the material constituting the anode, and is not definitely decided, but it is usually in a range of from 10 nm to 50 μm, and preferably from 50 nm to 20 μm.

A value of electric resistance of the anode is preferably 10³ Ω/□ or less, and more preferably 10² Ω/□ or less.

The anode can be colorless and transparent or colored and transparent. For extracting luminescence from the anode side, it is preferred that a light transmittance of the anode is 60% or higher, and more preferably 70% or higher. The light transmittance can be measured by means well known in the art using a spectrophotometer.

Concerning the anode, there is a detailed description in “TOUMEI DENNKYOKU-MAKU NO SHINTENKAI (Novel Developments in Transparent Electrode Films)” edited by Yutaka Sawada and published by C.M.C. in 1999, the contents of which are incorporated by reference herein. In the case where a plastic substrate of a low heat resistance is applied, it is preferred that ITO or IZO is used to obtain an anode prepared by forming the film at a low temperature of 150° C. or lower.

<Cathode>

The cathode in the present invention generally has a function as a cathode for injecting electrons to the organic compound layer, and there is no particular restriction as to the shape, the structure, the size and the like of the cathode. Accordingly, the cathode may be suitably selected from among well-known electrodes according to the application and the purpose of the light-emitting element.

As the materials constituting the cathode, for example, metals, alloys, metal oxides, electric conductive compounds, and mixtures thereof may be used, wherein materials having a work function of 4.5 eV or less are preferred. Specific examples thereof include alkali metals (e.g., Li, Na, K, Cs or the like); alkaline earth metals (e.g., Mg, Ca or the like); gold; silver; lead; aluminum; sodium-potassium alloys; lithium-aluminum alloys; magnesium-silver alloys; rare earth metals such as indium and ytterbium; and the like. They may be used alone, but it is preferred that two or more of them are used in combination from the viewpoint of satisfying both of stability and electron injectability.

Among these, as the materials for constituting the cathode, alkaline metals or alkaline earth metals are preferred in view of electron injectability, and materials containing aluminum as the major component are preferred in view of excellent preservation stability. The term “material containing aluminum as the major component” refers to a material that material exists in the form of aluminum alone; alloys comprising aluminum and 0.01% by weight to 10% by weight of an alkaline metal or an alkaline earth metal; or mixtures thereof (e.g., lithium-aluminum alloys, magnesium-aluminum alloys and the like).

As for materials for the cathode, they are described in detail in JP-A Nos. 2-15595 and 5-121172, the contents of which are incorporated by reference herein.

A method for forming the cathode is not particularly limited, but it may be formed in accordance with a well-known method. For instance, the cathode may be formed on the substrate described above, for example, in accordance with a method which is appropriately selected from among wet methods such as a printing method, and a coating method and the like; physical methods such as a vacuum deposition method, a sputtering method, and an ion plating method and the like; and chemical methods such as CVD and plasma CVD) methods and the like, while taking the suitability to a material constituting the cathode into consideration.

For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, and a lift-off method or a printing method may be applied.

In the organic luminescence element, a position at which the cathode is to be formed is not particularly restricted, and it may be suitably selected according to the application and the purpose of the light-emitting element. The cathode is preferably formed on the organic compound layer. In this case, the cathode may be formed on either the whole or a part of the organic compound layer.

Furthermore, a dielectric material layer made of a fluoride or the like of an alkaline metal or an alkaline earth metal may be inserted between the cathode and the organic compound layer with a thickness of 0.1 nm to 5 nm.

A thickness of the cathode may be suitably selected dependent on materials for constituting the cathode and is not definitely decided, but it is usually in a range of from 10 nm to 5 μm, and preferably rom 50 nm to 1 μm.

Moreover, the cathode may be transparent or opaque. The transparent cathode may be formed by preparing a material for the cathode with a small thickness of from 1 nm to 10 nm, and further laminating a transparent electric conductive material such as ITO or IZO thereon.

10) Protective Layer

According to the present invention, the whole organic EL element may be protected by a protective layer.

A material contained in the protective layer may be one having a function to prevent penetration of substances such as moisture, oxygen and the like, which accelerate deterioration of the element, into the element.

Specific examples thereof include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one comonomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, or a transfer method may be applied.

11) Sealing

The whole organic electroluminescence element according to the present invention may be sealed with a sealing cap.

Furthermore, a moisture absorbent or an inert liquid may be used to seal a space defined between the sealing cap and the light-emitting element. Although the moisture absorbent is not particularly limited. Specific examples thereof include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, molecular sieve, zeolite, magnesium oxide and the like. Although the inert liquid is not particularly limited, specific examples thereof include paraffins; liquid paraffins; fluorine-based solvents such as perfluoroalkanes, perfluoroamines, perfluoroethers and the like; chlorine-based- solvents; silicone oils; and the like.

12) Production Method of Element

The respective layers that constitute the element in the present invention can be preferably formed by any method of dry film forming methods such as a vapor deposition method and a sputtering method, and wet film forming methods such as a dipping method, a spin coating method, a dip coating method, a casting method, a die coating method, a roll coating method, a bar coating method and a gravure coating method.

Among these, from the viewpoints of light-emission efficiency and durability, the dry film forming methods are preferable. In the case of the wet film forming methods, a residual coating solvent unfavorably damages the light-emitting layer.

Particularly preferably, a resistance heating vacuum deposition method is used. In the resistance heating vacuum deposition method, since only a substance that can be transpired by heating under a vacuum atmosphere can be efficiently heated, whereby the element is not exposed to a high temperature, the element is advantageously subjected to less damage.

The vacuum deposition method is a method in which, in a vacuumed vessel, a deposition material is heated to vaporize or sublimate to deposit on a surface of an adherend disposed at a slightly distanced position to form a thin film. Depending on the deposition material and the adherend, resistance heating, electron beam, high-frequency induction, laser or the like is used to carry out heating. Among these, the one that can form a film with at the lowest temperature is the resistance heating vacuum deposition method. Although it cannot form a film with a material having a high sublimation temperature, all materials that have a low sublimation temperature can form a film in a state where the adherent material is hardly thermally affected.

The sealing film material in the present invention is characterized in that it can form a film by means of the resistance heating vacuum deposition method.

A conventional sealing material such as silicon oxide, being high in sublimation temperature, has been impossible to deposit by means of resistance heating. Furthermore, in a vacuum deposition method such as an ion plating method generally described in known examples, since a vaporizing portion becomes such a high temperature as several thousands of degrees centigrade to adversely thermally affect and modify an adherent material, this method is not appropriate as a production method of a sealing film of an organic EL element that is particularly easily affected by heat or UV rays.

13) Driving Method

In the organic electroluminescence element according to the present invention, when DC (AC components may be contained as occasion arises) voltage (usually 2 volts to 15 volts) or DC is applied across the anode and the cathode, luminescence can be obtained.

For the driving method of the organic electroluminescence element according to the present invention, the driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308 are applicable.

All publications, patent applications, and technical standards mentioned in this specification are herein incorporated by reference to the same extent as if each individual publication, patent application, or technical standard was specifically and individually indicated to be incorporated by reference.

What is claimed is:

1. A display by an active matrix drive in which a plurality of pixels are independently controlled, wherein each pixel comprises at least two sub-pixels that emit light having the same color as each other by application of current to the sub-pixels, and at least one of the sub-pixels is provided with an optical filter at a light extraction side of the sub-pixel.

2. The display according to claim 1, wherein the optical filter has a transmission density for reducing a light quantity to a range of from 5% to 60%.

3. The display according to claim 1, wherein a light emission area of the sub-pixel having the optical filter is smaller than a light emission area of a sub-pixel that does not have the optical filter.

4. The display according to claim 1, wherein a number of gradations of the sub-pixel having the optical filter is smaller than a number of gradations of a sub-pixel that does not have the optical filter.

5. The display according to claim 1, wherein a light-emitting element used in the sub-pixel having the optical filter and a light-emitting element used in a sub-pixel that does not have the optical filter emit light having the same color, and both of the light-emitting elements are substantially similar except for the presence or absence of the optical filter on a light extraction surface and a difference in light emission areas of the light-emitting elements.

6. The display according to claim 1, wherein the pixel comprises a charge injection light-emitting element, and gradation reproduction of the pixel is controlled by current values to be applied.

7. The display according to claim 6, wherein the light-emitting element is an organic electroluminescence element.

8. The display according to claim 7, wherein a light-emitting material of the organic electroluminescence element is a phosphorescent material.

9. The display according to claim 7, wherein the organic electroluminescence element is a top-emission organic electroluminescence element.

10. The display according to claim 1, wherein the display is a full color display.
